(19) United States
(12) Patent Application Publication
(10) Pub. No.: US 2024/0014140 A1
(43) Pub. Date: Jan. 11, 2024

(54) Fan-out Wafer Level Package having Small Interposers

(71) Applicant: Wei Hu Koh, Irvine, CA (US)

(72) Inventor: Wei Hu Koh, Irvine, CA (US)

(21) Appl. No.: 17/861,229

(22) Filed: Jul. 10, 2022

(51) Int. Cl. H01L 23/538; H01L 25/065; H01L 23/00; H01L 23/498; H01L 23/31

(52) U.S. Cl. CPC H01L 23/5384; H01L 25/0655; H01L 24/48; H01L 23/5383; H01L 23/49816; H01L 23/3128; H01L 25/0652; H01L 25/0657; H01L 24/16; H01L 2224/48137; H01L 2224/48155; H01L 2224/16225; H01L 2224/45147; H01L 2224/45664; H01L 2224/45144; H01L 2224/45139; H01L 2224/45124; H01L 24/45

(57) ABSTRACT

A plurality of small copper-filled TSV (through silicon via) interposer slivers dispersed in a fan-out wafer level package (FOWLP) for wire bonding interconnections forms a hybrid FOWLP/interposer multichip package that avoids the use of expensive large 2.5D TSV interposer modules for heterogeneous integration and for chiplets. Package fabrication on reconstituted wafers or panels can follow either the chip-first or RDL-first process.

### FIELD OF INVENTION

This invention relates to semiconductor integrated circuit packaging using interposer for heterogeneous integration; more specifically, this invention pertains to a wafer level fan-out multichip packaging for System-in-Package (SiP) and chiplets.

### BACKGROUND OF THE INVENTION

Fan-out wafer level packaging (FOWLP) has been used in commercial volume production for semiconductor IC (integrated circuit) chips for mobile devices and other applications. In the chip-first, face-up fabrication, a reconstituted wafer is formed with the backside of IC chips attached to a temporary carrier and encapsulated by an epoxy molding compound (EMC). The top side EMC material is then removed to expose the chip I/O (input/output) contact pads for connections to a redistribution layer (RDL) that is built on top of the EMC with embedded chips. Solder balls are then attached to the outer pads connected to the RDL rerouting traces; the finished reconstituted wafer is tested and lastly diced to form individual FOWLP packages.

FOWLP packages generally have a thinner body thickness compared to typical ball grid array (BGA) packages that require the use of a substrate for solder ball attachment. For thin form-factor mobile and wearable devices, FOWLP packages are ideal with their lightweight and thin thickness. However, during RDL fabrication on the reconstituted wafers, RDL trace alignment to the individual I/O contact pads on each chip is critical for good production yield and reliability. The alignment accuracy and hence production yield, however, can be affected by die-shift of the encapsulated chips during and after EMC molding of the reconstituted wafers. There is therefore a need to resolve the RDL trace to chip I/O pad alignment concerns by improving the ease of alignment accuracy during RDL fabrication on a reconstituted wafer.

For high performance computing (HPC) applications, on the other hand, heterogeneous integration using a side-by-side 2.5D (D for dimension) System-in-Package (SiP) is formed by integrating various SOC (system on chip) chips such as a CPU (central processing unit) or a GPU (graphic processing unit) to memory ICs on a platform, an interposer module that acts as an intermediate substrate containing copper-filled TSV (through silicon via) and a surface RDL. Conductive traces within the RDL reroute the chip I/O signals to the package substrate through the interposer TSV connections; and the chip/interposer module assembly is mounted on the package substrate for assembly to the PCB (printed circuit board). Because the interposer module is a platform supporting a group of different chips, the size of an interposer can be substantially bigger than that of the individual chips. For example, a large SOC chip may be 15 mm×15 mm, but the underlying interposer module for a SiP package could be 30 mm×30 mm to include the large SOC and other chips. Furthermore, a typical 2.5D interposer module contains many TSV arrays and at least one surface RDL. When large pieces of interposer modules are fabricated from a silicon wafer, the wafer edge utilization ratio is reduced and the production yield generally is significantly lower than that of small chips. Thus, due to the relative high cost of making large-sized TSV interposer modules, 2.5D heterogeneous integration packages remains expensive to fabricate and are usually reserved for high-performance HPC and high-end applications.

To reduce the high cost of fabricating large-sized TSV interposer modules, it is necessary to reduce the interposer sizes while eliminating the surface RDL layers. However, such kind of small interposers would not be able to act as a platform supporting a large number of chips required in a high-performance SiP package. In order to utilize the use of low-cost, small-sized interposers, alternate chip integration schemes for a multichip package or a SiP are needed.

Yet another disadvantage of the 2.5D interposer packages is the need for a substrate to connect to the interposer module, which results in three levels of interconnections from the chip I/O to the assembled PCB: 1) Chip to interposer, 2) Interposer to substrate, and 3) Substrate to PCB board. With more intermediate bump connections, there can be additional production yield loss and also a performance reliability issue. In addition, the package bill of materials (BOM) cost is higher, while the package body could also be thick.

It is therefore desirable to have a heterogeneous integration multichip or SiP package that has the thin form-factor of a FOWLP package, no substrate, and maintains the high-performance level of a 2.5D interposer package without incurring the use of a large, expensive interposer module. Even more advantageously, such packages may be applied in heterogeneous integration of chiplet packaging that requires special chiplet-to-chiplet connections using embedded silicon bridges.

### SUMMARY OF THE INVENTION

The present invention combines the high-volume production-proven method of fan-out wafer level packaging (FOWLP) processes and the use of small-sized, uncomplicated copper-filled TSV interposers for heterogeneous integration of different chips to form a high-performance SiP or multichip package. Such hybrid FOWLP-small interposer packages avoid the use of a large, expensive interposer module as the platform and follow the proven technique of fan-out wafer level reconstituted wafer fabrication. Such hybrid packages further provide a relaxed alignment requirement, hence higher yield, between the RDL traces and the chip I/O pads by spreading out the tight I/O pitches to different interposer slivers using the proven and mature technique of wire bonding.

The key enabler component for this hybrid packaging invention is the use of different simple, tiny TSV interposer slivers that are cut out from large dummy, copper-filled TSV silicon wafers with no active circuitry. Following the naming convention of chiplets, the copper-filled TSV small interposer slivers should be named “interposerlets;” but an easier, abbreviated name, “interpolet” is used here to represent a small TSV interposer sliver. By eliminating the use of large-sized and low-yielding complex interposer modules with RDL, the package BOM cost is reduced. Furthermore, connections between the IC chips and the interpolets are made using copper wire bonding, a proven and low-cost interconnection method compared to flip chip or micro-bump, copper pillar bump (CPB) interconnections.

Each interpolet has arrays of copper-filled TSV with patterns designed for fan-out wire bonding to the I/O pads on its mating chip or chips. There is no RDL on the interpolet wire bonding surface because both the wire bonding angles and wire lengths are custom-adjusted for fan-out connections from the chip I/O pads to the nearby interpolet TSV that are at a wider pitch. Furthermore, direct copper wire to copper pad bonding can be made without the need of additional bonding pad metallization such as nickel and palladium. A monolayer coating of Organic Solderability Preservatives (OSP) is applied to the interpolet surfaces to cover all exposed TSV copper and pads for oxidation prevention.

During the initial die-placement step on a FOWLP reconstituted wafer, the interpolets are placed next to their respective mating chips for short wire bonding. In an interpolet, the copper-filled TSV may have a diameter comparable to that of the bonding wire, typically in the range between 15-30 um. For good wire bonding, it may be necessary to create a larger wire bonding pad on the bonding surface of the copper-filled TSV. For instance, a 35 um×35 um square pad may be fabrication on top of a 20 um diameter TSV for wire bonding by copper wire that is 18-um in diameter; while the TSV pitch is kept at 50 um. These are the design details for those skilled in the art in making custom interpolet designs for wire bonding. For chips having low I/O counts, it is possible to build the interpolets with larger-sized TSV at a wider pitch. For instance, a 35 um diameter TSV that would allow direct copper bonding using thin wires that are 20 um or less.

The number and pattern of TSV in each interpolet is therefore tailor-made for fan-out wire bonding for all data, clock, power and ground signals from its mating chip or chips. For instance, a 3 mm×5 mm sized interpolet may contain as many as 5000 TSV at a pitch of 50 um. Hence, one small interpolet may be shared for fan-out wire bonding by two or even more IC chips. To form the silicon interpolets, a large, dummy silicon wafer with copper-filled TSV can be diced into many tiny slivers. Alternatively, glass, ceramics, or organic laminates panels with copper-filled TSV may be used.

Following the chip-first fan-out reconstituted wafer fabrication process, the IC chips and their adjacent interpolets are placed on and attached to a temporary carrier, face-up. Wire bonding is then applied for either chip-to-chip or chip-to-interpolet connections. Wire bonding is used in the majority of semiconductor packages and has shown to be feasible for high-frequency data rates in the Gigahertz (GHz) range. It is also one of the most reliable and inexpensive methods for fan-out electrical interconnection. Depending on the design and performance needs, the wire materials can be copper, palladium plated copper, gold, silver, or aluminum.

After wire bonding, the populated reconstituted wafer is molded by an EMC (epoxy molding compound) encapsulation and cured. The temporary carrier is then removed to expose the backsides of all the IC chips and the interpolets. RDL (redistribution layer) is then fabricated on the molded reconstituted wafer to seal the package bottom surface and reroute the interpolet TSV bottom contacts to the external solder ball pads through conductive traces. After completion of the RDL, solder balls are attached to the reconstituted wafer RDL outer layer pads. After testing, individual SiP packages are obtained by singulating the tested reconstituted wafer.

Besides the chip-first, die face-up approach, the RDL-first, chip-last method can also be used in making the hybrid FOWLP/interposer packages. After a RDL layer is fabricated on a temporary carrier, selected main chips such as a CPU (central processing unit) or a GPU (graphic processing unit) are flip-chip bonded to the RDL pads with the die face-down. The adjacent interpolets nearby are also bonded to the RDL contact pads using micro-bumps attached to the TSV bottom copper openings. The rest of other chips, such as memory and chiplets, are placed on the RDL face-up. Wire bonding is then applied to connect these face-up chips to their respective mating interpolets so that the chip signals are rerouted and connected to the CPU or GPU through the interpolets and the bottom RDL. Moreover, such auxiliary chips or chiplets can be placed either side-by-side like a 2.5D package, or stacked on the backside of larger chips like a 3D stacked chip package.

Without using any large interposer modules like a conventional 2.5D package, the thin hybrid FOWLP/Interpolet package can maintain a thin body thickness for mobile devices and other applications. Such packages could also be comprised of a group of chiplets and their controlling chips to form a chiplet packaging, using wire bonding for chiplet-to-chiplet connections.

### BRIEF DESCRIPTION OF THE DRAWINGS

The drawings are diagrammatic representations of exemplary aspects of the present invention and are neither limiting nor necessarily drawn to scale.

FIG. 1 illustrates a prior art 2.5D multichip package using a large TSV interposer module with an integrated RDL on top of the interposer and a package substrate connected to the interposer bottom.

FIG. 2 is the cross-sectional view of a FOWLP multichip package having two chips; one side of the chip I/O are connected by chip-to-chip wire bonding, and the other side of chip I/O are wire bonded to interpolets.

FIG. 3 is a perspective view of the two-die FOWLP multichip package with a first plurality of chip-to-chip wire bonding and a second plurality of chip-to interpolet fan-out wire bonding.

FIG. 4 shows the cross-sectional view of a FOWLP/interpolet package having two shared interpolets in between three chips and two outside interpolets for chip outer edge fan-out wire bonding.

FIG. 5 is the top view of the FOWLP package layout having three chips wire bonded to two shared interpolets in-between and two outside interpolets for fan-out wire bond connections.

FIG. 6 is the cross-sectional view of a large center chip wire-bonded to its side interpolets and two stacked small chips also wire-bonded to the same interpolets.

FIG. 7 is the plane view of a multichip package layout having five chips and four corner interpolets placed side-by-side and interconnected by different fan-out wire bonding.

FIG. 8 is the cross-sectional view of a 3D stacked multiple chip FOWLP package with the lower flip chip face-down and connected to the RDL by micro-bumps, while two stacked chips on top are connected to their respective interpolets using wire bonding for fan-out connection to the RDL below.

FIG. 9 is the cross-sectional view of a simple interpolet structure with an array of copper-filled TSV have relatively large diameters for direct wire bonding without wire bonding pads.

FIG. 10 is the cross-sectional view of a simple interpolet having an array of thin copper TSV and wire bonding pads on both ends.

FIG. 11 shows the perspective view of an interpolet sliver and an expanded top view of the via-in-pad (VIP) wire bond pads; one large bonding pad is connected to two adjacent TSV for multiple wire bonding.

### DETAILED DESCRIPTION OF THE INVENTION

By way of illustration, the following detailed description refers to the accompanying drawings showing the details of various aspects of this invention disclosure.

The term chip refers to an integrated circuit (IC) die that can be a SOC (system on chip), MCU (micro controller unit), FPGA (field-programmable gate array) or memories such as DRAM, SRAM, and NAND; it also includes various types of chiplet in the illustrative drawings here. The term interpolet is used to represent a small copper-filled TSV interposer sliver, similar to a chiplet that is to a small sized chip.

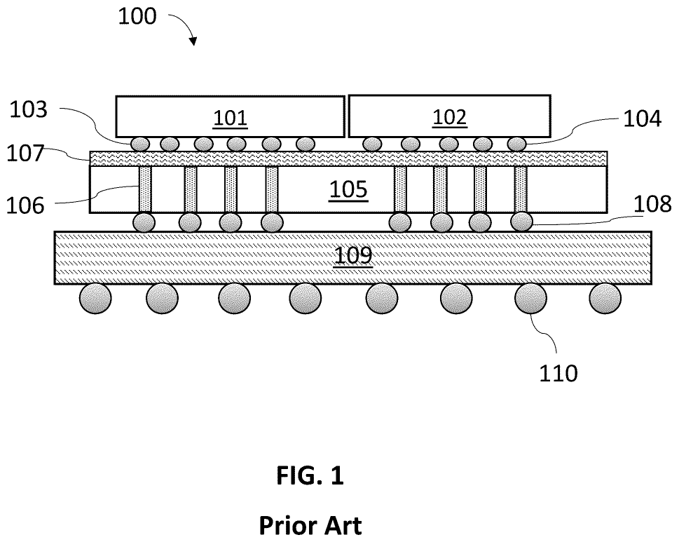

A conventional 2.5D interposer package is illustrated by FIG. 1 to show the prior art of heterogeneous integration of multiple chips on a large piece of silicon TSV interposer module. In FIG. 1, a 2.5D package 100 without encapsulation is shown having two IC chips 101 and 102, respectively, attached to the RDL (redistribution layer) 107 of interposer 105 by micro-bumps 103 on chip 101 and micro-bumps 104 on chip 102. Interposer module 105 has a plurality of vertical copper-filled TSV arrays 106 linking the top RDL 107 to the bottom bumps 108. The interposer module 105 and its chip 101 and chip 102 subassembly are mounted onto a package substrate 109 having bottom lead-free C4 (controlled collapse chip connection) solder balls 110 for SMT (surface mount technology) assembly to a PCB motherboard (not shown). Package 100 requires the use of an expensive component, the TSV interposer module 105, and three levels of interconnection: micro-bumps 103 and 104 on chip 101 and 102, respectively; bumps 108 at the bottom of interposer 105; and solder balls 110 on the package substrate 109. With the intermediate interposer 105 and three levels of bump interconnections, the package 100 body height is generally thicker than typical FOWLP packages that do not have an interposer and a substrate.

Because the large-sized interposer module 105 requires intricate patterns of TSV array 106 and RDL 107, the fabrication cost of interposer module 105 remains prohibitively expensive due to low wafer edge utilization and poor yield from a silicon wafer. Some alternatives, including use of non-silicon materials such as glass or organic substrates, are being developed. Such materials may be used in a panel format to reduce the edge waste; however, materials different from silicon may pose other issues such as mismatch of CTE (coefficient of thermal expansion). Ideally, therefore, the best interposer material for silicon IC chips is still silicon, and prior art 2.5D packages such as device 100 using a large-sized silicon interposer 105 are generally reserved for high-end applications such as for high performance computing (HPC), networking, and datacenter applications.

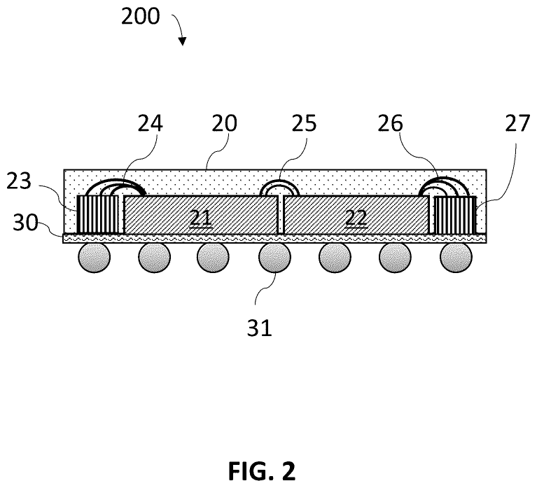

FIG. 2 illustrates a simple design concept scheme of using two small-sized interpolets in a FOWLP package to replace the use of a large-sized interposer module and a supporting substrate in a conventional 2.5D package. The cross-sectional view of device 200 shows that two adjacent chips 21 and 22 are connected to each other by wire bond bundle 25 for chip-to-chip interconnection, while chip 21 is also linked to interpolet 23 on the outside by fan-out wires 24 and chip 22 to interpolet 27 on the other end by fan-out wires 26. All of the signal outputs from chip 21 are routed through interpolet 23 TSV arrays to the bottom RDL 30, and all of the signal outputs from chip 22 are routed through the interpolet 27 TSV arrays to RDL 30, and finally from RDL 30 to the outer solder balls 31. Encapsulant 20 is applied on the reconstituted wafer after the wire bonding step is completed.

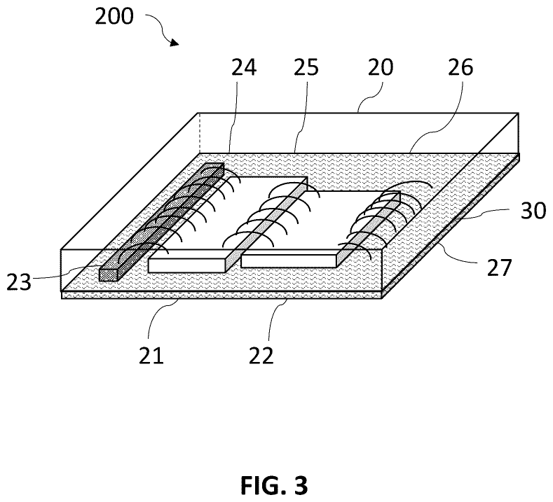

To further illustrate the layout configuration, FIG. 3 shows a perspective view of package 200 with no solder balls underneath RDL 30. RDL 30 is fabricated on a reconstituted wafer after encapsulant 20 is molded; its internal conductive traces are connected to the bottom TSV contacts in interpolet 23 and interpolet 27 for rerouting to the bottom solder balls. Wire bond bundle 25 is chip-to-chip connection between chip 21 and chip 22; while the chip 21 signal outputs connect to interpolet 23 through fan-out wire bond bundle 24 and chip 22 outputs to interpolet 27 through fan-out wire bond bundle 26. With multiple fan-out rows of TSV contacts in interpolet 23 and interpolet 27, the alignment of internal conductive traces in RDL 30 is made much easier due to wider interconnection pitches.

Although FIG. 3 shows that just two interpolets 23 and 27 are used for rerouting all signals from chip 21 and chip 22 to RDL 30, additional interpolets can be added if needed to accept more fan-out wire bonding from chip 21 and chip 22.

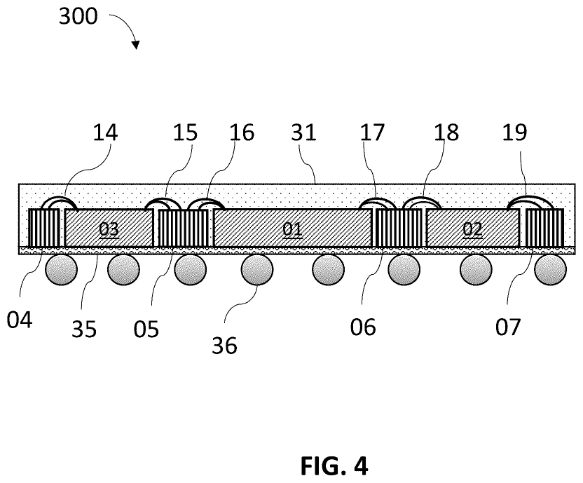

The use of interpolets shared among multiple chips is illustrated by FIG. 4, wherein the cross-sectional view of package 300 is shown. Chip 01 connects to interpolet 06 through multi-row wire bundle 17; and chip 02 also connects to the shared interpolet 06 by multi-row wire bundle 18. The other side of chip 01 is connected to interpolet 05 by wire bundle 16, while chip 03 shares the same interpolet 05 using wire bundle 15. Chip 02 is further connected to interpolet 07 on the outer edge by wire bundle 19, and chip 03 connected to interpolet 04 through wire bundle 14. The bottom TSV contacts of interpolets 04, 05, 06, and 07, respectively, are coupled to the internal conductive traces of RDL 35 for rerouting to the bottom solder balls 36 of package 300. Encapsulant 31 covers all the chips and wires placed on RDL 35. The fabrication can be made using a silicon reconstituted wafer, chips face-down, or using panel as a fan-out panel level package (FOPLP).

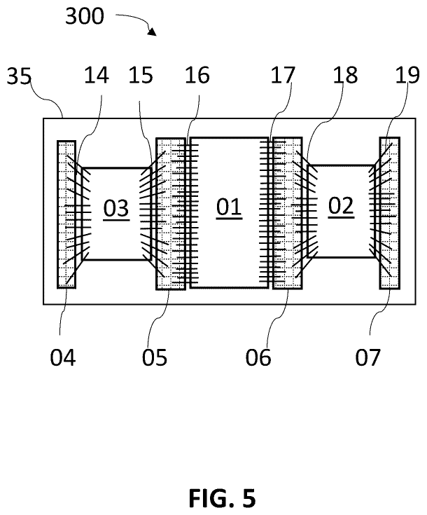

The plane layout of package 300 is also shown by FIG. 5 in a top view. Chip 01 side I/O pads are wire bonded by wire bundle 16 to interpolet 05, and to interpolet 06 by wire bundle 17 in a multi-row manner so that the TSV pitches on interpolet 16 and interpolet 17 are spread out for wider pitches that allow for easier contact alignment by the RDL 35 connecting traces. Chip 02 is connected to interpolet 06 on one side by fan-out wire bundle 18, and to interpolet 07 on the other side by fan-out wire bonding bundle 19. Similarly, chip 03 connects to interpolet 05 by fan-out wire bonding bundle 15 and to interpolet 04 by fan-out wire bonding bundle 14. Hence, all of the chip I/O connections are rerouted though interpolet 04, interpolet 05, interpolet 06, and interpolet 07 to the connecting traces internal to RDL 35. If needed, more interpolets can be placed on the horizontal sides of chip 01, chip 02, and chip 03 for more fan-out wire interconnections.

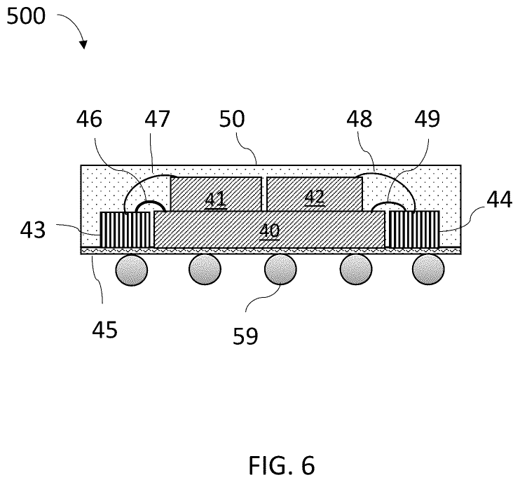

In FIG. 6, a stacked chip option is shown by package 500, wherein chip 41 and chip 42 are stacked on top of a face-up bottom chip 40, which uses wire bond bundle 46 to connect to interpolet 43 and wire bond bundle 49 to connect to interpolet 44. Stacked chip 41 connects to the shared interpolet 43 using wire bond bundle 47, and stacked chip 42 connects to interpolet 44 by wire bond bundle 48. Thus, 3D stacked chip assembly is possible even for face-up wire bond chips under the encapsulation 50. The bottom RDL 45 has internal conductive traces linked to the TSV bottom contacts of interpolet 43 and interpolet 44 for rerouting to the external solder balls 59.

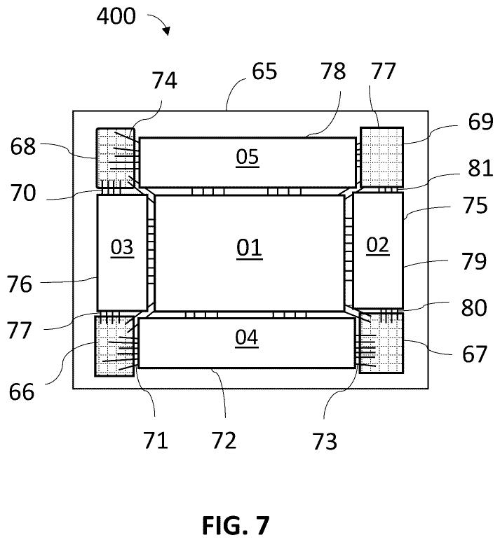

To further illustrate the flexibility in placement options of the interpolets and different fan-out wire bonding schemes, FIG. 7 illustrates a plane view of a package 400 having an underlying RDL 65. Chip 01 could be a large CPU or GPU, and chip 02 and chip 03 could each be a group of interconnected chiplets; chip 04 and chip 05 could each be a memory stack such as a HBM (high bandwidth memory). Chip-to-chip interconnections between chip 01 and chip 02 is through wire bond bundle 75, and between chip 01 and chiplet 03 by wire bond bundle 76. Chip 01 further has chip-to-chip connections to chip 04 through wire bond bundle 72 and to chip 05 through wire bond bundle 78. Chip 02 also has wire bond bundle 80 connected to interpolet 67 and wire bond bundle 81 to interpolet 69. Chip 03 has wire bond bundle 77 connected to interpolet 66 and wire bond bundle 70 to interpolet 68.

Similarly, chip 05 has wire bond bundle 74 and wire bond bundle 77 connected to interpolet 68 and 69, respectively. Chip 04 has wire bond bundle 71 linked to interpolet 66 and wire bond bundle 73 linked to interpolet 67. Lastly, chip 01 corners have four diagonal wire bond bundles 79 coupled to the four corner interpolets 66, 67, 68, and 69, respectively.

The chip and interpolet floor placement are flexible based on the number, size, and shape of the chips and interpolets. FIG. 5 and FIG. 7 are just two illustrations of different layout schemes as examples for interconnections by fan-out wire bonding. The key advantage of this invention remains in the flexibility in designing suitable small, inexpensive interpolet slivers with the right amount of TSV contacts and wider pitches for alignment connection to the underlying RDL traces with high yield.

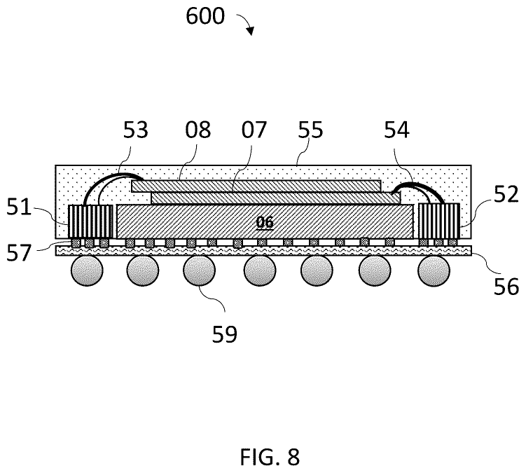

Furthermore, the assembly of multiple chips in this FOWLP package invention is not limited to the chip-first, die face-up process. In the RDL-first approach, chips are connected to the RDL face-down with micro-bumps. FIG. 8 illustrates a face-down package 600 using the RDL-first approach, wherein the main center chip 06 is flip-chip bonded to its underlying RDL 56 by micro-bumps 57. At the same time, adjacent interpolet 51 and interpolet 52 are also bonded to RDL 56 using micro-bumps 57. Two thin chips, chip 07 and chip 08, are stacked on top of main chip 06 face-up, and wire bonding bundle 54 connect chip 07 to interpolet 52, while wire bond bundle 53 connects chip 08 to interpolet 51. Thus, all of the signal connections from chip 06, chip 07, and chip 08 are rerouted to the bottom solder balls 59 through the RDL 56. Package 600 is therefore a 3D stacked FOWLP package using the low-cost interpolets 51 and 52 and fan-out wire bonding for some of the multiple chips inside the packages.

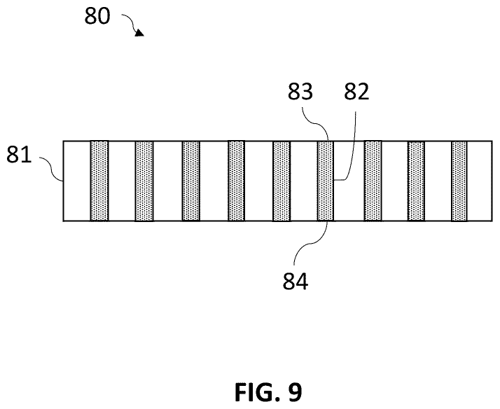

The key enabling components for such hybrid FOWLP packages are the tiny copper-filled TSV interpolet slivers (or, interpolets). For low I/O count chips such as chiplets and memory, the size of an interpolet can be small and the TSV diameters can be made large enough to accept direct copper wire bonding to the copper-filled TSV without bond pads. FIG. 9 illustrates the cross-sectional view of a simple interpolet 80 having a TSV array 82 with opening sizes bigger than the bonding wires suitable for direct wire bonding to the top exposed surface 83. For copper oxidation protection, both the top exposed surface 83 and the bottom exposed surface 84 are covered by an OSP (organic solderability preservatives) coating (not shown).

As an example, the TSV 82 diameter can be 30-um or 40-um so that thin copper wires less than 20 um can be bonded directly to the exposed copper surface 83 of TSV 82. Interpolet 80 can be fabricated from a large, dummy silicon TSV wafer by dicing off different-sized interpolet slivers.

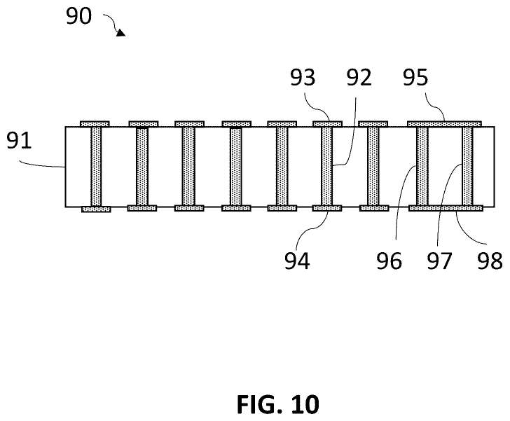

FIG. 10 illustrates the cross-section of another interpolet 90 having a silicon body 91 with an array of TSV 92, TSV 96, and TSV 97. The top end of TSV 92 is capped with a surface wire bonding pad 93, and the top ends of TSV 96 and TSV 97 are capped with a common wire bonding pad 95. Shared bonding pad 95 can be used for bonding by multiple power and ground wires that require a higher current-carrying capacity. The bottom openings of all TSV are also capped with bonding pads, as shown by pad 94 on TSV 93. Such bottom pads may be optional for linking to the RDL later. In the case for the RDL-first fabrication, interpolet 90 with bottom pads 94 and pad 98 may have micro-bumps attached first before bonding to the RDL. Both the top surface pads 93, 95 and bottom surface pads 94 and 98 are covered by the OSP coating for oxidation protection.

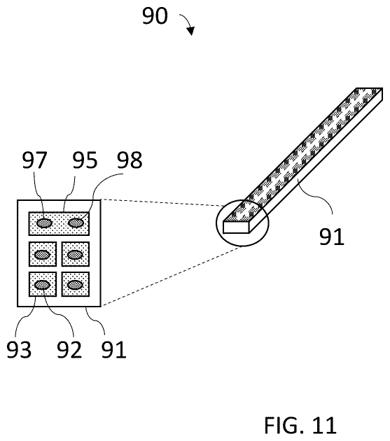

To further illustrate the structure of interposer sliver 90, FIG. 11 shows a perspective view of the sliver body 91, and an expanded partial top view of the surface wire bond pads. Pad 93 is a VIP (via in pad) on top of TSV 92, while the shared common pad 95 is on top of TSV 97 and TSV 98. Pad 95 can be bonded with multiple wires for higher current-carrying capacity used for power and ground wires. The interpolet sliver 90 can be fabricated from dummy copper-filled TSV silicon wafers, but glass panels or other materials such as ceramics or organic composite materials may also be used to make the copper-filled TSV interpolets.

By combining the use of inexpensive tiny interpolet slivers and flexible fan-out wire bonding interconnections, multiple chips and their accompanying interpolets can be placed on a fan-out reconstituted wafer in different manners, either chip-first or RDL-first with side-by-side or 3D stacking configurations. The chips may either be placed face-up for wire bonding, or some of the chips placed face-down in the RDL-first approach. For the RDL-first approach, the interpolet slivers may also need micro bumps for bonding to the finished RDL during the die-attach, die-bonding steps.

1. An integrated circuit package, comprising:
integrated circuit chips having face-up input/output wire bonding pads;
small copper-filled TSV (through silicon via) interposer slivers having an OSP (organic solderability preservatives) coating covering all exposed TSV copper surfaces;
a first plurality of chip-to-chip wire bonding interconnections;
a second plurality of chip-to-interposer sliver wire bonding interconnections;
an encapsulation encasing all chips, wires, interposer slivers; and
a redistribution layer (RDL) having internal conductive traces coupling the small interposer sliver TSV bottom contacts to solder balls attached to the RDL outer bonding pads.

2. The package of claim 1, wherein at least one integrated circuit chip is connected to the small TSV interposer slivers by wire bonding.

3. The package of claim 1, wherein two or more integrated circuit chips are connected to a shared small TSV interposer sliver by wire bonding.

4. The package of claim 1, wherein at least one of the integrated circuit chips is a chiplet.

5. The package of claim 1, wherein the wire bonding wires are connected to the small interposer sliver TSV copper openings without surface bonding pads.

6. The package of claim 1, wherein both sides of the copper-filled TSV openings in the small interposer slivers are covered by VIP (via-in-pad) metal pads for wire bonding.

7. The package of claim 6, wherein at least one wire bonding pads on the small interposer sliver connect two or more copper-filled TSV for multiple wire bonding.

8. The package of claim 1, wherein the integrated circuit chips and the small interposer slivers are placed side-by-side on the RDL.

9. The package of claim 1, wherein at least one integrated circuit chip is stacked on another chip.

10. The package of claim 1, wherein at least one integrated circuit chip is connected to the RDL face-down by flip chip bumps.

11. The package of claim 10, wherein at least one small interposer sliver is connected to the RDL by TSV bottom micro-bumps.

12. The package of claim 10, wherein at least one integrated circuit chip is stacked on top of another chip.
